(19) United States
(12) Patent Application Publication
(10) Pub. No.: US 2013/0237703 A1
(43) Pub. Date: Sep. 12, 2013

(54) Visible Light-Absorbing Complex, Triazine-Based Dendritic Polymer, and Organic Photovoltaic Device

(71) Applicant: NATIONAL CHI NAN UNIVERSITY, Puli (TW)

(72) Inventors: Long-Li LAI, Taichung City (TW); Shun-Ju Hsu, Dongshih Township (TW); Hui-Chu Hsu, Beidou Township (TW)

(73) Assignee: National Chi Nan University, Puli (TW)

(21) Appl. No.: 13/866,881

(22) Filed: Apr. 19, 2013

Related U.S. Application Data
(62) Division of application No. 12/591,650, filed on Nov. 25, 2009, now abandoned.

(30) Foreign Application Priority Data
Nov. 28, 2008 (TW) 097146241

(51) Int. Cl. H01L 51/00

(52) U.S. Cl. CPC H01L 51/0067
USPC 544/198

(57) ABSTRACT

A visible light-absorbing complex includes an electron acceptor and an electron donor, the electron donor having a triazine-based dendritic polymer formed of a core group (C) and branch groups, each of the branch groups being composed of terminal groups (P) and a triazine-based moiety group. The triazine-based dendritic polymer is represented by the following formula (I):

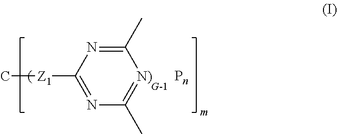

wherein G indicates the generation number, “G-1” indicating the layer number of the branch groups, n being the number of the terminal groups, m being the number of the branch groups,
wherein Z₁ is a divalent group containing O or N, and an atom of Z₁ bonding to the triazine group should be O or N; and
wherein, when G is 1, the core group should be a triazine-based core group having a triazine ring, and an atom of each of the terminal groups bonding to the triazine ring should be O or N.

### CROSS-REFERENCE TO RELATED APPLICATION

This application claims priority of Taiwanese Patent Application No. 097146241, filed on Nov. 28, 2008.

### BACKGROUND OF THE INVENTION

1. Field of the Invention

This invention relates to a visible light-absorbing complex for an organic photovoltaic device, a triazine-based dendritic polymer for preparing the visible light-absorbing complex, and an organic photovoltaic device containing the visible light-absorbing complex.

2. Description of the Related Art

Solar energy has been brought up to be a solution for the current energy crisis. Solar energy at 400 to 800 nm wavelength exhibits greatest intensity. Therefore, a product (e.g., a compound, a complex, etc.) with absorption at 400 to 800 nm could be a good material for a solar cell.

Recently, a polymer solar cell has been proposed, which is a type of organic solar cell (or organic chemistry photovoltaic cell) that produces electricity from sunlight using polymer. In J. Am. Chem. Soc., vol. 127, p 13030-13038, Kimihisa Yamamoto et. al disclose a dendritic polymer composed of a triphenylamine core and phenylazomethine dendrons used as a hole-transport unit for a solar cell. After the dendritic polymer is added with SnCl₂, the absorption band for the mixture is observed at 350 to 450 nm. Since the mixture exhibits absorption at a relatively narrow range of visible wavelength, the application thereof in the solar energy field is limited.

Daniela Goldmann et al. disclose alkoxy-substituted 2,4,6-triarylamino-1,3,5-triazine used as an electron donor for controlling the arrangement of liquid crystal molecules by charge transfer (see Angew. Chem. Int. Ed., Vol. 39, No. 10, p 1851-1854, 2000). Although the triazine-based compound has been disclosed to be an electron donor in the liquid crystal field, its application in the solar energy field is neither suggested nor disclosed in the published literature.

Therefore, there is a need in the art to provide a visible light-absorbing complex exhibiting absorption at a relatively wide range of visible wavelength.

### SUMMARY OF THE INVENTION

Therefore, the object of the present invention is to provide a visible light-absorbing complex, a triazine-based dendritic polymer for preparing the visible light-absorbing complex, and an organic photovoltaic device containing the visible light-absorbing complex.

According to one aspect of this invention, there is provided a visible light-absorbing complex for an organic photovoltaic device including an electron acceptor and an electron donor, the electron donor having a triazine-based dendritic polymer formed of a core group (C) and branch groups emanating from the core group (C), each of the branch groups being composed of terminal groups (P) and a triazine-based moiety group, the triazine-based dendritic polymer being represented by the following formula (I):

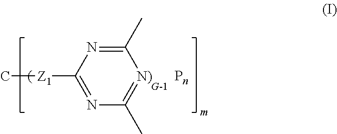

wherein G indicates the generation number of the triazine-based dendritic polymer and is an integer greater than 0, “G-1” indicating the layer number of the branch groups, n being the number of the terminal groups and representing 2^{(G-1)}, and m being the number of the branch groups emanating from the core group and ranging from 2 to 4,

wherein Z₁ of the triazine-based moiety group is a divalent group containing O or N, and an atom of Z₁ bonding to the triazine group of the triazine-based moiety group should be O or N, and

wherein, when G is 1, the core group should be a triazine-based core group having a triazine ring, and an atom of each of the terminal groups bonding to the triazine ring of the triazine-based core group should be O or N.

According to another aspect of this invention, there is provided a triazine-based dendritic polymer including a core group (C′) and branch groups emanating from the core group, each of the branch groups being composed of terminal groups (P′) and a triazine-based moiety group, the triazine-based dendritic polymer being represented by the following formula (I′):

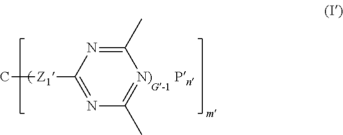

wherein G′ indicates the generation number of the triazine-based dendritic polymer and is an integer greater than 0, “G′-1” indicating the layer number of the branch groups, n′ being the number of the terminal groups and representing 2^{(G′-1)}, and m′ being the number of the branch groups emanating from the core group and ranging from 2 to 4,

wherein Z′₁ is

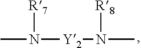

and when R′₇ and R′₈ are independently a C₁˜C₁₀ alkyl group, Y′₂ is a C₁-C₁₀ alkylene group, 1,4-cyclohexylene, 1,3-cyclohexylene, meta-phenylene, para-phenylene, or when R′₇ and R′₈ together form a C₂˜C₁₀ alkenyl group, Y′₂ is a C₁-C₁₀ alkylene group, and with the proviso that Z′₁ cannot be

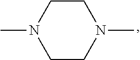

and

wherein, when G′ is 1, the core group should be a triazine-based core group having a triazine ring, and an atom of each of the terminal groups bonding to the triazine ring of the triazine-based core group should be O or N.

According to yet another aspect of this invention, there is provided an organic photovoltaic device comprising the aforesaid visible light-absorbing complex.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a schematic view of the first preferred embodiment of an organic photovoltaic device according to this invention;

FIG. 2 is a schematic view of the second preferred embodiment of an organic photovoltaic device according to this invention; and

FIG. 3 is a UV-Vis spectrum of a visible light-absorbing complex containing G₂-N˜N-G₂/TFBQ/TCNE.

### DETAILED DESCRIPTION OF THE PREFERRED EMBODIMENTS

A visible light-absorbing complex for an organic photovoltaic device according to this invention includes an electron acceptor and an electron donor. The electron donor has a triazine-based dendritic polymer formed of a core group (C) and branch groups emanating from the core group (C). Each of the branch groups is composed of terminal groups (P) and a triazine-based moiety group. The triazine-based dendritic polymer can be represented by the following formula (I):

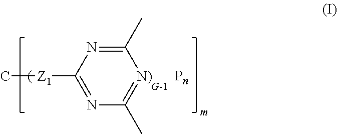

In formula (I), G indicates the generation number of the triazine-based dendritic polymer and is an integer greater than 0, “G-1” indicates the layer number of the branch groups, n is the number of the terminal groups and represents 2^{(G-1)}, and m is the number of the branch groups emanating from the core group and ranges from 2 to 4.

Z₁ of the triazine-based moiety group is a divalent group containing O or N, and an atom of Z₁ bonding to the triazine group of the triazine-based moiety group should be O or N. Preferably, an atom of Z₁ bonding to the core group (C) is O or N. More preferably, the atoms of Z₁ bonding to the core group (C) and the triazine group of the triazine-based moiety group are N.

When G is 1, the core group should be a triazine-based core group having a triazine ring, and an atom of each of the terminal groups bonding to the triazine ring of the triazine-based core group should be O or N.

Preferably, in the triazine-based moiety group, at least one of the atoms of Z₁ bonding to the respective one of the triazine groups, should be N.

Preferably, an atom of Z₁ bonding to the core group is O or N, and more preferably, is N.

Preferably, in each occurrence, Z₁ is

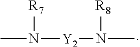

When R₇ and R₈ are independently H or a C₁˜C₁₀ alkyl group, Y₂ is a C₁-C₁₀ alkylene group, 1,4-cyclohexylene, 1,3-cyclohexylene, meta-phenylene, para-phenylene, or when R₇ and R₈ together form a C₂˜C₁₀ alkylene group, Y₂ is a C₁-C₁₀ alkylene group.

More preferably, Z₁ per se is a non-conjucated group which provides good solubility for the dendritic polymer in the organic solvent.

Preferably, the generation number (G) is greater than 1. Considering that the dendritic polymer having a large generation number is difficult to prepare and the molecular structure thereof might be bent due to large and long branch groups which would influence the electron transporting property, the triazine-based dendritic polymer according to this invention preferably has a generation number (G) ranging from 1 to 4.

Preferably, the core group is a triazine-based core group. When m is 2, the triazine-based core group is

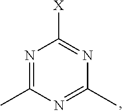

and X is any substituent group that can bond to the triazine ring of the core group by virtue of substitution reaction.

Preferably, X is halogen, a C₁˜C₂₀ alkyl group, a C₁˜C₂₀ aromatic group, OR₀,

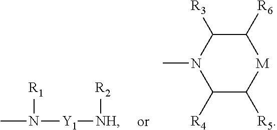

R₀ is a C₁˜C₂₀ alkyl group or a C₁˜C₂₀ aromatic group, R₁ and R₂ are independently H or a C₁˜C₁₀ alkyl group, Y₁ is 1,4-cyclohexylene, 1,3-cyclohexylene, meta-phenylene, para-phenylene, or a C₁-C₁₀ alkylene group, M is NH, O, S, CH₂, N—R′, or CH—R″, R₃, R₄, R₅, and R₆ are independently H or a methyl group, in which R′ is a C₁˜C₂₀ alkyl group, a C₁˜C₂₀ aromatic group,

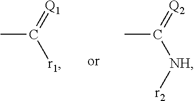

in which Q₁ and Q₂ are independently O or S, r₁ and r₂ are independently a C₁˜C₂₀ alkyl group or a C₁˜C₂₀ aromatic group, R″ is OH, Or₃,

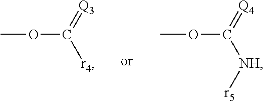

in which Q₃ and Q₄ are independently O or S, and r₃, r₄, and r₅ are independently a C₁˜C₂₀ alkyl group or a C₁˜C₂₀ aromatic group.

When m is 3, the triazine-based core group is

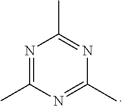

When m is 4, the triazine-based core group is

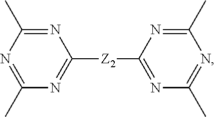

and Z₂ is a divalent group containing O or N and has the same definition as Z₁.

Preferably, M is NH or O, and more preferably, M is NH.

In the examples of this invention, X is Cl or

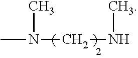

As shown in Formula (I), the total number of the terminal groups of the triazine-based dendritic polymer is m*2^{(G-1)}. Preferably, in each occurrence, the terminal group is independently —NR₉R₁₀ or

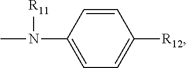

wherein R₉ and R₁₀ are independently H, a C₁˜C₁₀ alkyl group, -E₁-R₁₃, or -E₂-OR₁₄, and E₁ and E₂ are independently meta-phenylene or para-phenylene, R₁₃ and R₁₄ are independently H or a C₁˜C₂₀ alkyl group, R₁₁ is H or a C₁˜C₁₀ alkyl group, and R₁₂ is H, a C₁˜C₂₀ alkyl group, —OR₁₅, -E₃-R₁₆, or -E₄-OR₁₇, and E₃ and E₄ are meta-phenylene, and R₁₅, R₁₆, and R₁₇ are independently H or a C₁˜C₂₀ alkyl group. More preferably, in each occurrence, P is —NR₉R₁₀, and R₉ and R₁₀ are independently a C₄-C₈ alkyl group.

The electron acceptor used in the present invention can be any commercially available electron acceptor that exhibits electron transporting property when working with the aforesaid electron donor of this invention. Examples of the electron acceptor include tetrafluoro-p-benzoquinone (TFBQ), 7,7,8,8-tetracyano-p-quinodimethane (TCNQ), and tetracyanoethylene (TCNE).

In the present invention, a novel triazine-based dendritic polymer is also disclosed and has a structure represented by the following formula (I′):

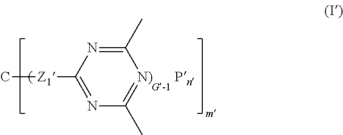

wherein C′, P′, G′, G′-1, m′, and n′ have the same definitions as C, P, G, G-1, m, and n in formula (I),

wherein Z′₁ is

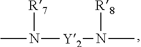

and when R′₇ and R′₈ are independently a C₁˜C₁₀ alkyl group, Y′₂ is a C₁-C₁₀ alkylene group, 1,4-cyclohexylene, 1,3-cyclohexylene, meta-phenylene, para-phenylene, or when R′₇ and R′₈ together form a C₂˜C₁₀ alkenyl group, Y′₂ is a C₁-C₁₀ alkylene group, and with the proviso that Z′₁ cannot be

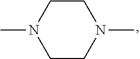

and

wherein, when G′ is 1, the core group should be a triazine-based core group having a triazine ring, and an atom of each of the terminal groups bonding to the triazine ring of the triazine-based core group should be O or N.

The visible light-absorbing complex according to the present invention can be used to prepare an organic photovoltaic device.

### General Preparative Methods

The methods for preparing the dendritic polymers (I) and (I′), the visible light-absorbing complex, and the organic photovoltaic device are provided below to aid one skilled in the art in synthesizing these compounds and polymers, with more detailed examples in the following Example section.

The dendritic polymer can be prepared by a convergent method or a divergent method. Preferably, the dendritic polymer of this invention is prepared using a convergent method. Details of the preparative method can be found in the disclosures in J. Org. Chem., vol. 73, No. 2, p. 485-490 (2008) and Org. Lett. Vol. 8, No. 8, p. 1541-1544, (2006), and are briefly outlined below (see the following scheme). For the sake of illustration, (C₈H₁₇)₂ is used as a terminal group and dimethylethylenediamino group is used as a Z₁ group.

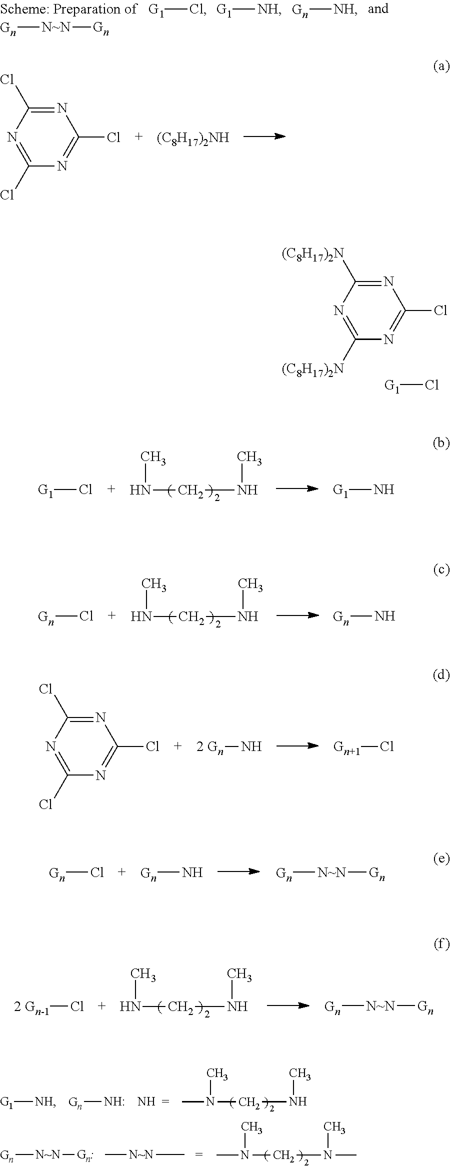

As shown in the aforesaid reaction (a), cyanuric chloride is first reacted with dioctylamine so as to obtain G₁-Cl (a dendron, i.e., m=2), in which G₁ means the first generation of the dendritic polymer, G₁-Cl is then reacted with dimethylethylenediamine so as to form G₁-NH (see reaction (b)). As shown in reaction (d), two G₁-NH molecules are reacted with cyanuric chloride so as to form G₂-Cl (second generation), and G₂-Cl is then reacted with dimethylethylenediamine so as to form G₂-NH (see reaction (c)). The third generation of the dendron, the fourth generation of the dendron, and others are formed based on the same procedures. The dendrimer (Gₙ-N˜N-Gₙ, i.e., m=4) is formed by reacting Gₙ-Cl and Gₙ-NH (see reaction (e)) or by reacting two Gₙ₋₁-Cl with dimethylethylenediamine (see reaction (f)).

Preferably, the reactions (a) and (d) are conducted at a temperature ranging from 10 to 35° C. in the presence of an organic solvent. Examples of the organic solvent include dichloromethane, tetrahydrofuran (THF), EtOH, acetone, and acetonitrile. In an example of this invention, the reaction temperature is 25° C. and the solvent thus used is dichloromethane. To be specific, each of the reactants is dissolved in the dichloromethane, followed by mixing the reactant solutions in an ice bath under stirring. After adding with triethylamine, the mixture is further reacted at room temperature.

Preferably, the reactions (b) and (c) are conducted at a temperature ranging from 20 to 45° C. in the presence of an organic solvent. Examples of the organic solvent include dichloromethane, THF, EtOH, acetone, and acetonitrile.

Preferably, the reaction (f) is conducted at a temperature ranging from 50 to 100° C. in the presence of an organic solvent. Examples of the organic solvent include dichloromethane, THF, EtOH, acetone, and acetonitrile. In an example of this invention, the reaction (f) is conducted at 80° C. and the solvent thus used is THF. To be specific, each of the reactants is dissolved in THF, followed by mixing the reactant solutions at room temperature under stirring. After adding triethylamine, the mixture is further reacted at 80° C.

It is noted that, in each reaction, triethylamine is used to neutralize HCl formed during reaction.

A visible light-absorbing complex according to this invention is prepared by mixing a dendritic polymer of this invention with at least one electron acceptor in the presence of an organic solvent. The organic solvent can be any solvent that permits the dendritic polymer and the electron acceptor to be dissolved therein. Examples of the organic solvent include, but are not limited to, dichloromethane, THF, ethanol, acetone, and acetonitrile.

The visible light-absorbing complex dissolved in the organic solvent can be applied onto a substrate, e.g., a glass substrate, followed by dissipating the organic solvent, thereby obtaining a substrate coated with the visible light-absorbing complex.

The organic photovoltaic device according to this invention includes a photovoltaic element containing the visible light-absorbing complex of this invention. For example, the organic photovoltaic device is a solar cell.

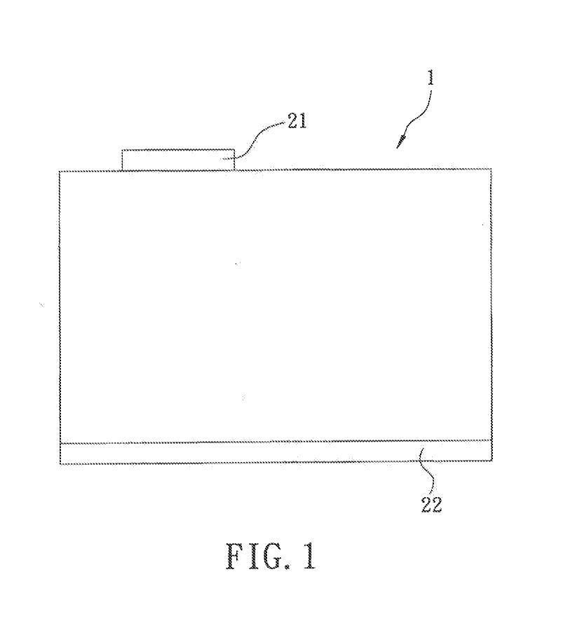

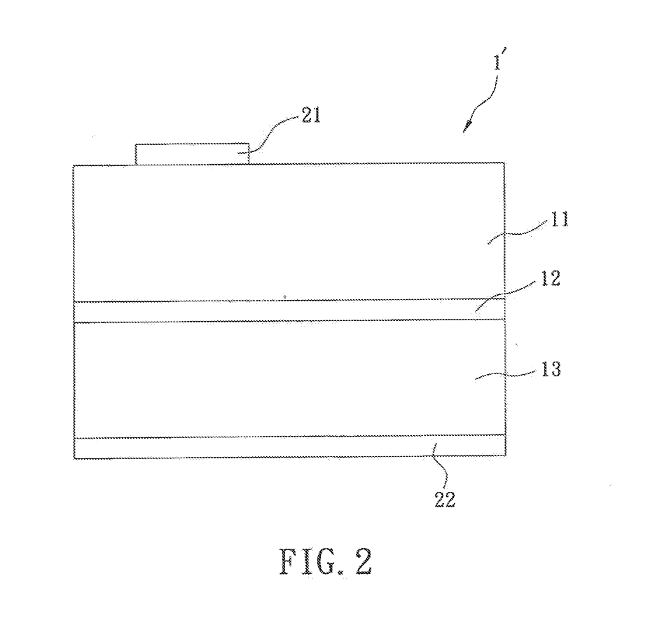

Each of FIGS. 1 and 2 shows the preferred embodiment of an organic photovoltaic device according to this invention. As shown in FIG. 1, the first preferred embodiment of an organic photovoltaic device according to this invention includes a photovoltaic element 1 containing the visible light-absorbing complex of this invention and two output electrodes 21, 22 disposed on the photovoltaic element 1 and spaced apart from each other by the photovoltaic element 1. Preferably, in addition to the visible light-absorbing complex of this invention, the photovoltaic element 1 further includes a hole transporting material (e.g., p type organic semiconductor). As shown in FIG. 2, the second preferred embodiment of an organic photovoltaic device according to this invention includes a photovoltaic element 1′ containing an electron transporting layer 11, a light-absorbing layer 12, and a hole transporting layer 13, and two output electrodes 21, 22 disposed on the electron transporting layer 11 and the hole transporting layer 13, respectively. Preferably, the electron transporting layer 11 is an n type organic semiconductor, the light-absorbing layer 12 includes the visible light-absorbing complex of this invention, and the hole transporting layer 13 is a p type organic semiconductor. However, it should be noted that the organic photovoltaic device is not limited to the aforesaid structures.

### General Preparative Methods

### General Procedure

1. ¹H-NMR spectra were obtained using a Bruker AMX300 Solution-NMR spectrometer.

2. Mass spectra were obtained using a JEOL JMS-700 instrument.

3. Elemental analyses (EA) were performed using an Elementar Vario EL III instrument.

4. UV-Visible spectra were obtained using a Varian Cary 50 Bio instrument.

### Preparation of the Dendritic Polymer of the Present Invention

### Example 1

### Preparation of G₁-Cl Having the Following Formula

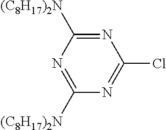

9.22 g (50.00 mmole) of cyanuric chloride was dissolved in 100 ml of anhydrous dichloromethane so as to form a cyanuric chloride solution. 24.15 g (100.00 mmole) of dioctylamine (commercially available from ACROS, CAS no. 1120-48-5) was dissolved in 100 ml of anhydrous dichloromethane so as to form a dioctylamine solution. The dioctylamine solution was slowly added into the cyanuric chloride solution, followed by stirring for 1 hour in an ice bath. 14.04 ml (100.00 mmole) of triethylamine was added into and reacted with the mixture for 5 minutes. The mixture was then reacted at room temperature, and was monitored using thin-layer chromatography (TLC) every 30 minutes to determine whether the reaction was complete during the reaction. After the reaction was complete (about 24 hours), the mixture was washed twice with 5 molar equivalents of potassium hydroxide solution, and then washed once with water. The combined organic layers of the extracted solution were treated with anhydrous magnesium sulfate to remove water from the organic solvent, followed by evaporation of the organic solvent at reduced pressure. After chromatography, 29.30 g of a pale yellow liquid product was obtained (98.9% yield).

### Structure Identification

The structure of the product thus obtained was identified using NMR and MASS. ¹H-NMR (AMX 300 δ (D-CDCl₃)): 0.88 (t, 12H, J=5.1 Hz, 4×CH₃), 1.27-1.29 (m, 40H, 20×CH₂), 1.55 (S_{br}, 8H, 4×CH₂), 3.42 (t, 4H, J=6.0 Hz, 2×CH₂), 3.47 (t, 4H, J=5.7 Hz, 2×CH₂). MASS calcd for C₃₅H₆₈ClN₅ (M)⁺: 594.5. found: 594.5.

### Example 2

### Preparation of G₁-NH Having the Following Formula

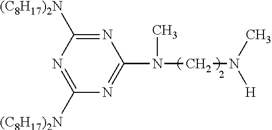

6.55 g (74.30 mmole) of dimethylethylenediamine (commercially available from ACROS, CAS no. 110-70-3) was dissolved in 100 ml THF solution so as to form a dimethylethylenediamine solution. 14.69 g (24.77 mmole) of the G₁-Cl compound was dissolved in 100 ml of THF solution, followed by addition of the dimethylethylenediamine solution thereinto. The mixture was reacted at 40° C. and was monitored using thin-layer chromatography (TLC) every 30 minutes to determine whether the reaction was complete. After the reaction was complete (about 23 hours), the mixture was washed twice with 7 molar equivalents of potassium hydroxide solution, and then washed once with water. The combined organic layers of the extracted solution were treated with anhydrous magnesium sulfate to remove water from the organic solvent, followed by evaporation of the organic solvent at reduced pressure. After chromatography, 12.66 g of a pale yellow liquid product was obtained (79.1% yield).

### Structure Identification

The structure of the product thus obtained was identified using NMR and MASS. ¹H-NMR (AMX 300 δ (D-CDCl₃)): 0.87 (t, 12H, J=5.7 Hz, 4×CH₃), 1.27 (S_{br}, 40H, 20×CH₂), 1.57 (S_{br}, 8H, 4×CH₂), 2.45 (s, 3H, 1×CH₃), 2.81 (t, 2H, J=6.3 Hz, 1×CH₂), 3.09 (s, 3H, 1×CH₃), 3.44 (S_{br}, 8H, 4×CH₂), 3.66 (t, 2H, J=6.3 Hz, 1×CH₂). LRMS calcd for C₃₉H₇₉N₇(M)⁺: 646.6. found: 646.8; HRMS calcd for C₃₉H₇₉N₇(M)⁺: 646.6431. found: 646.6476.

### Example 3

### Preparation of Dendron (G₂-Cl) Having the Following Formula

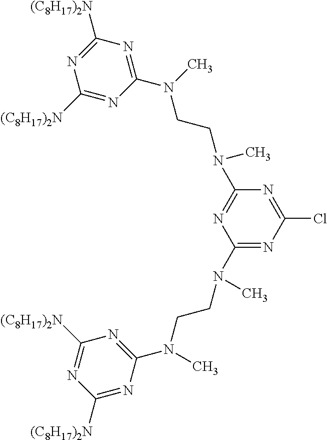

The steps for preparing the dendron (G₂-Cl) in Example 3 were similar to those of Example 1. The differences reside in that 24.15 g of dioctylamine was replaced by 12.29 g (19.02 mmole) of G₁-NH prepared in Example 2, the amount of cyanuric chloride was 1.75 g (9.51 mmole), the amount of triethylamine was 2.67 ml (19.02 mmole), and the amount of the potassium hydroxide solution was 17 molar equivalents. 12.93 g of a pale yellow liquid product was obtained (98.9% yield).

### Structure Identification

The structure of the product thus obtained was identified using NMR, MASS, and EA. ¹H-NMR (AMX 300 δ (D-CDCl₃)): 0.88 (t, 24H, J=6.0 Hz, 8×CH₃), 1.28 (S_{br}, 80H, 40×CH₂), 1.56-1.59 (m, 16H, 8×CH₂), 3.04-3.15 (s, 12H, 4×CH₃), 3.44 (S_{br}, 16H, 8×CH₂), 3.74 (S_{br}, 8H, 4×CH₂). MASS calcd for C₈₁H₁₅₆ClN₁₇ (M)⁺: 1403.3. found: 1403.3. Anal. calcd for C₈₁H₁₅₆ClN₁₇: N, 16.96%; C, 69.31%; H, 11.20%. found: N, 16.73%; C, 69.17%; H, 11.30%.

### Example 4

### Preparation of Dendron (G₂-NH) Having the Following Formula

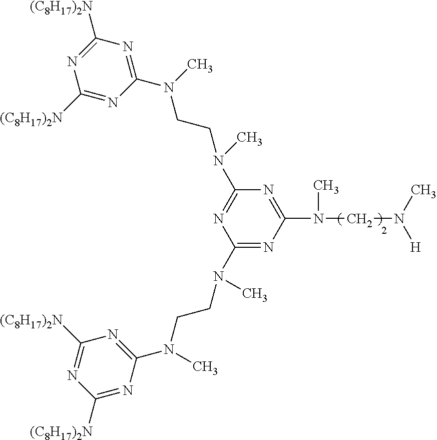

The steps for preparing the dendron (G₂-NH) in Example 4 were similar to those of Example 2. The differences reside in that 14.69 g of G₁-Cl was replaced by 16.94 g (12.07 mmole) of G₂-Cl prepared in Example 3, the amount of dimethylethylenediamine was 3.19 g (36.20 mmole), and the amount of the potassium hydroxide solution was 19 molar equivalents. 11.15 g of a pale yellow liquid product was obtained (92.3% yield).

### Structure Identification

The structure of the product thus obtained was identified using NMR, MASS, and EA. ¹H-NMR (AMX 300 δ (D-CDCl₃)): 0.87 (t, 24H, J=5.7 Hz, 8×CH₃), 1.28 (S_{br}, 80H, 40×CH₂), 1.57 (S_{br}, 16H, 8×CH₂), 2.45 (s, 3H, 1×CH₃), 2.83 (S_{br}, 2H, 1×CH₂), 3.08+3.12 (2s, 15H, 5×CH₃), 3.45 (S_{br}, 16H, 8×CH₂), 3.71 (S_{br}, 10H, 5×CH₂), MASS calcd for C₈₅H₁₆₈N₁₉ (M+H)⁺: 1456.4. found: 1456.8. Anal, calcd for C₈₅H₁₆₈N₁₉: N, 18.29%; C, 70.15%; H, 11.57%. found: N, 18.17%; C, 70.00%; H, 11.63%.

### Example 5

### Preparation of Dendron (G₃-Cl) Having the Following Formula

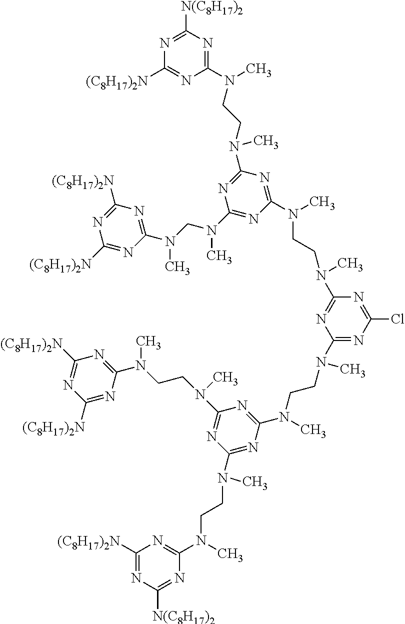

The steps for preparing the dendron (G₃-Cl) in Example 5 were similar to those of Example 11. The differences reside in that 24.15 g of dioctylamine was replaced by 11.15 g (7.66 mmole) of G₂-NH prepared in Example 4, the amount of cyanuric chloride was 0.71 g (3.83 mmole), the amount of triethylamine was 2.67 ml (19.02 mmole), and the amount of the potassium hydroxide solution was 47 molar equivalents. 8.83 g of a pale yellow liquid product was obtained (88.2% yield).

### Structure Identification

The structure of the product thus obtained was identified using NMR, MASS, and EA. ¹H-NMR (AMX 300 δ (D-CDCl₃)): 0.87 (t, 48H, J=5.7 Hz, 16×CH₃), 1.28 (S_{br}, 160H, 80×CH₂), 1.56 (S_{br}, 32H, 16×CH₂), 3.08+3.12 (2s, 36H, 12×CH₃), 3.45 (S_{br}, 32H, 16×CH₂), 3.73 (S_{br}, 24H, 12×CH₂). MASS calcd for C₁₇₃H₃₃₃N₄₁Cl (M+H)⁺: 3022.7. found: 3023.3. Anal. calcd for C₁₇₃H₃₃₃N₄₁Cl: N, 19.00%; C, 68.75%; H, 11.07%. found: N, 19.00%; C, 68.70%; H, 11.14%.

### Example 6

### Preparation of Dendrimer (G₁-N˜N-G₁) Having the Following Formula

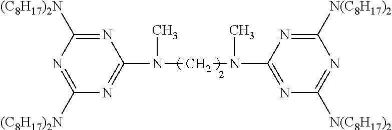

0.44 g (5 mmole) of dimethylethylenediamine was dissolved in 100 ml of THF solution so as to form a dimethylethylenediamine solution. 5.93 g (10.00 mmole) of the G₁-Cl compound obtained in Example 1 was dissolved in 100 ml of THF solution, followed by slow addition of the dimethylethylenediamine solution and 0.70 ml (5 mmole) of triethylamine in sequence thereinto. The mixture was reacted at 80° C. and was monitored using thin-layer chromatography (TLC) every 30 minutes to determine whether the reaction was complete. After the reaction was complete (about 23 hours), the mixture was washed twice with 5 molar equivalents of potassium hydroxide solution, and then washed once with water. The combined organic layers of the extracted solution were treated with anhydrous magnesium sulfate to remove water from the organic solvent, followed by evaporation of the organic solvent at reduced pressure. After chromatography, 4.25 g of a pale yellow liquid product was obtained (70.7% yield).

### Structure Identification

The structure of the product thus obtained was identified using NMR and MASS. ¹H-NMR (AMX 300 δ (D-CDCl₃)): 0.87 (t, 24H, J=5.4 Hz, 8×CH₃), 1.28 (S_{br}, 80H, 40×CH₂), 1.55 (S_{br}, 16H, 8×CH₂), 3.09 (S_{br}, 6H, 2×CH₂), 3.45 (s, 16H, 8×CH₂), 3.69 (S_{br}, 4H, 2×CH₂) MASS calcd for C₇₄H₁₄₇N₁₂ (M+H)⁺: 1205.0. found: 1205.0.

### Example 7

### Preparation of Dendrimer (G₂-N˜N-G₂) Having the Following Formula

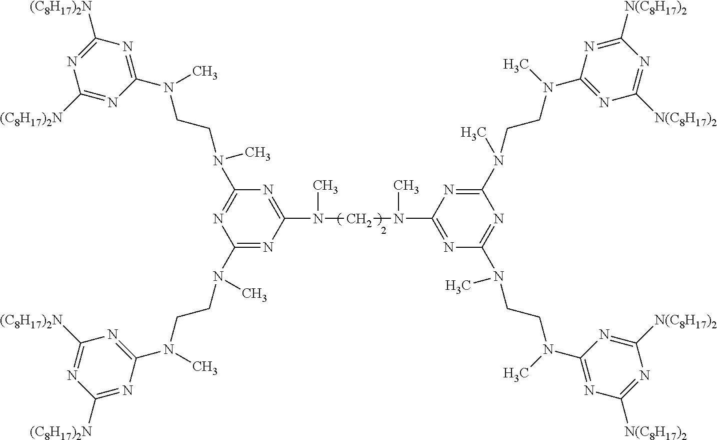

The steps for preparing the dendrimers in Example 7 were similar to those of Example 6. The differences reside in that 5.93 g (10.00 mmole) of the G₁-Cl compound was replaced by 25.85 g (18.42 mmole) of G₂-Cl, the amount of dimethylethylenediamine used in Example 7 was 0.81 g (9.20 mmole), and the amount of triethylamine used in Example 7 was 1.29 ml (9.20 mmole). 17.83 go a pale yellow liquid product was obtained (68.65 wt % yield).

### Structure Identification

The structure of the product thus obtained was identified using NMR, MASS, and EA. ¹H-NMR (AMX 300 δ (D-CDCl₃)): 0.89 (S_{br}, 48H, 16×CH₃), 1.29 (S_{br}, 160H, 80×CH₂), 1.59 (S_{br}, 32H, 16×CH₂), 3.10+3.14 (2s, 30H, 10×CH₃), 3.46 (S_{br}, 32H, 16×CH₂), 3.74 (S_{br}, 20H, 10×CH₂). ASS calcd for C₁₆₆H₃₂₃N₃₆ (M+H)⁺: 2823.6. found: 2823.3. Anal. calcd for C₁₆₆H₃₂₃N₃₆: N, 17.86%; C, 70.64%; H, 11.50%. found: N, 18.00%; C, 70.28%; H, 11.50%.

### Example 8

### Preparation of Dendrimer (G₃-N˜N-G₃) Having the Following Formula

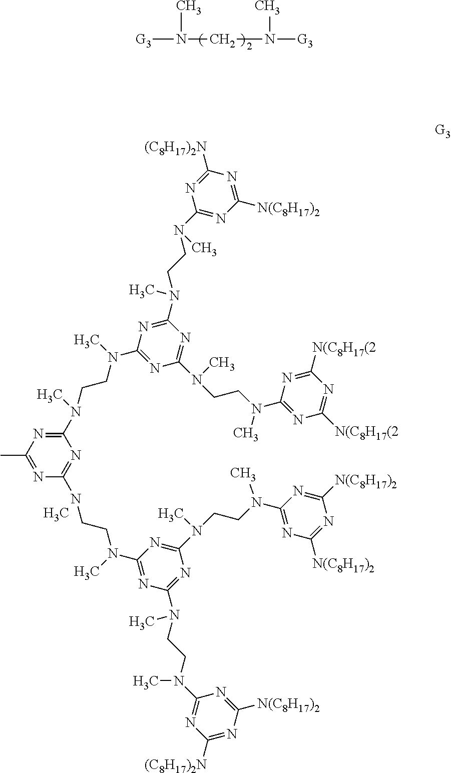

The steps for preparing the dendrimers in Example 8 were similar to those of Example 6. The differences reside in that 5.93 g (10.00 mmole) of the G₁-Cl compound was replaced by 3.82 g (1.26 mmole) of G₃-Cl, the amount of dimethylethylenediamine was 0.06 g (0.63 mmole), and the amount of triethylamine was 0.27 ml (1.91 mmole). 3.87 g of a pale yellow liquid product was obtained (50.5 wt % yield).

### Structure Identification

The structure of the product thus obtained was identified using NMR, MASS, and EA. ¹H-NMR (AMX 300 δ (D-CDCl₃)): 0.85 (t, 96H, J=5.1 Hz, 32×CH₃), 1.25 (S_{br}, 320H, 160×CH₂), 1.54 (S_{br}, 64H, 32×CH₂), 3.06+3.10 (2s, 78H, 26×CH₃), 3.42 (S_{br}, 64H, 32×CH₂), 3.70 (S_{br}, 52H, 26×CH₂). MASS calcd for C₃₅₀H₆₇₅N₈₄ (M+H)⁺: 6059.4. found: 6059.4. Anal. calcd for C₃₅₀H₆₇₅N₈₄: N, 19.42%; C, 69.37%; H, 11.13%. found: N, 19.20%; C, 69.37%; H, 11.12%.

### Example 9

### Preparation of the Dendrimer Having the Following Formula (II)

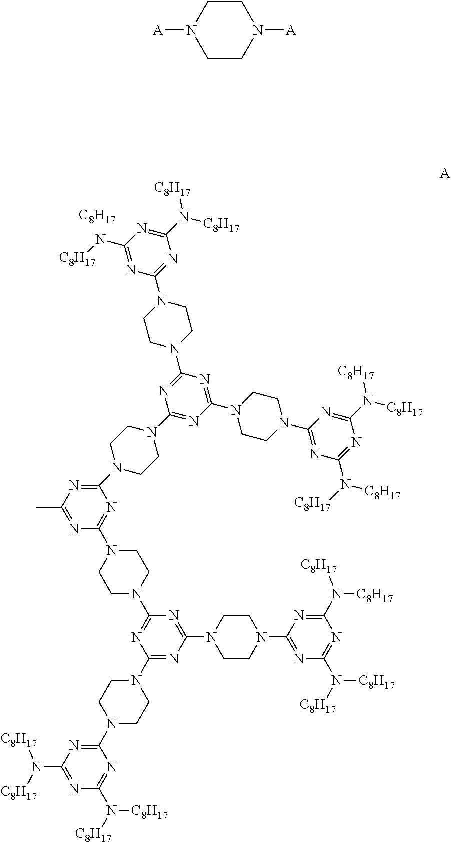

The method for preparing the dendrimer of formula (II) is based on the method set forth in J. Org. Chem., 73, pp. 485-490 (2008).

Experiments: Preparation of the Visible Light-Absorbing Complex of this Invention

A visible light-absorbing complex according to this invention was obtained by mixing a dendritic polymer as an electron donor and at least one electron acceptor in dichloromethane. For example, in Experiment 1, G₂-N˜N-G₂ prepared in Example 7, TFBQ, and TCNE (molar ratio 1:1:1) were dissolved in 10 ml dichloromethane. The UV-Visible absorption of the visible light-absorbing complex was then measured. In the present invention, the absorption in Experiment 1 was measured after dichloromethane was expelled (i.e., in a solid state), while absorption in each of Experiments 2-1 to 6 was measured in the presence of dichloromethane (i.e., in a liquid state). It can be predicted that, the absorption of a visible light-absorbing complex measured in the solid state would be stronger than that in the liquid state because of the shorter distance between the molecules of the visible light-absorbing complex in the solid state. The electron donor and the electron acceptor used in the experiments of this invention are set forth in Table 1.

TABLE 1

| | Visible | Visible |
|---|---|---|
| | light-absorbing | light-absorbing |
| Experiment | complex (molar ratio) | complex Conc. (M) |
| 1 | G₂-N~N-G₂/TFBQ/TCNE | — |
| | (1:1:1) | |
| 2-1 | G₂-N~N-G₂/TFBQ (1:1) | 1.0 × 10⁻² |
| 2-2 | G₂-N~N-G₂/TFBQ (1:1) | 5.0 × 10⁻³ |
| 2-3 | G₂-N~N-G₂/TFBQ (1:1) | 2.5 × 10⁻³ |
| 2-4 | G₂-N~N-G₂/TFBQ (1:1) | 1.3 × 10⁻³ |
| 2-5 | G₂-N~N-G₂/TFBQ (1:1) | 6.3 × 10⁻⁴ |
| 2-6 | G₂-N~N-G₂/TFBQ (1:1) | 3.1 × 10⁻⁴ |
| 2-7 | G₂-N~N-G₂/TFBQ (1:1) | 1.6 × 10⁻⁴ |
| 2-8 | G₁-N~N-G₁/TFBQ (1:1) | 2.5 × 10⁻³ |
| 2-9 | G₃-N~N-G₃/TFBQ (1:1) | 2.5 × 10⁻³ |
| 3-1 | G₂-N~N-G₂/TCNQ (1:1) | 1.0 × 10⁻² |
| 3-2 | G₂-N~N-G₂/TCNQ (1:1) | 5.0 × 10⁻³ |
| 3-3 | G₂-N~N-G₂/TCNQ (1:1) | 2.5 × 10⁻³ |
| 3-4 | G₂-N~N-G₂/TCNQ (1:1) | 1.3 × 10⁻³ |
| 3-5 | G₂-N~N-G₂/TCNQ (1:1) | 6.3 × 10⁻⁴ |
| 3-6 | G₂-N~N-G₂/TCNQ (1:1) | 3.1 × 10⁻⁴ |
| 3-7 | G₂-N~N-G₂/TCNQ (1:1) | 1.6 × 10⁻⁴ |
| 3-8 | G₁-N~N-G₁/TCNQ (1:1) | 1.0 × 10⁻² |
| 3-9 | G₃-N~N-G₃/TCNQ (1:1) | 1.0 × 10⁻² |
| 4-1 | G₂-N~N-G₂/TCNE (1:1) | 1.0 × 10⁻² |
| 4-2 | G₂-N~N-G₂/TCNE (1:1) | 5.0 × 10⁻³ |
| 4-3 | G₂-N~N-G₂/TCNE (1:1) | 2.5 × 10⁻³ |
| 4-4 | G₂-N~N-G₂/TCNE (1:1) | 1.3 × 10⁻³ |
| 4-5 | G₂-N~N-G₂/TCNE (1:1) | 6.3 × 10⁻⁴ |
| 4-6 | G₂-N~N-G₂/TCNE (1:1) | 3.1 × 10⁻⁴ |
| 4-7 | G₂-N~N-G₂/TCNE (1:1) | 1.6 × 10⁻⁴ |
| 4-8 | G₁-N~N-G₁/TCNE (1:1) | 2.5 × 10⁻³ |
| 4-9 | G₃-N~N-G₃/TCNE (1:1) | 2.5 × 10⁻³ |
| 4-10 | G₁-N~N-G₁/TCNE (1:1) | 3.1 × 10⁻⁴ |
| 4-11 | G₃-N~N-G₃/TCNE (1:1) | 3.1 × 10⁻⁴ |
| 5 | Formula (II)/TFBQ | 5.0 × 10⁻³ |
| | (1:1) | |
| 6 | Formula (II)/TCNE | 3.1 × 10⁻⁴ |
| | (1:1) | |

—: not obtained since the visible light-absorbing complex of Experiment 1 was in a solid state

For comparison, 2.5×10⁻² M of the dendrimer G₂-N˜N-G₂ dissolved in dichloromethane (hereinafter referred as CP1), 2.5×10⁻²M of TFBQ dissolved in dichloromethane (hereinafter referred as CP2), 3.9×10⁻⁵M of TCNQ dissolved in dichloromethane (hereinafter referred as CP3), and 1.0×10⁻²M of TCNE dissolved in dichloromethane (hereinafter referred as CP4) were used as comparative experiments. The greatest absorption band for CP1 was observed at a wavelength less than 300 nm, that for CP2 was observed at 337.07 nm, that for CP3 was observed at 398.93 nm, and that for CP4 was observed at a wavelength less than 300 nm. The results reveal that the comparative experiments exhibit no absorption band at 400 to 800 nm.

The absorption for each of the visible light-absorbing complexes according to this invention is illustrated below.

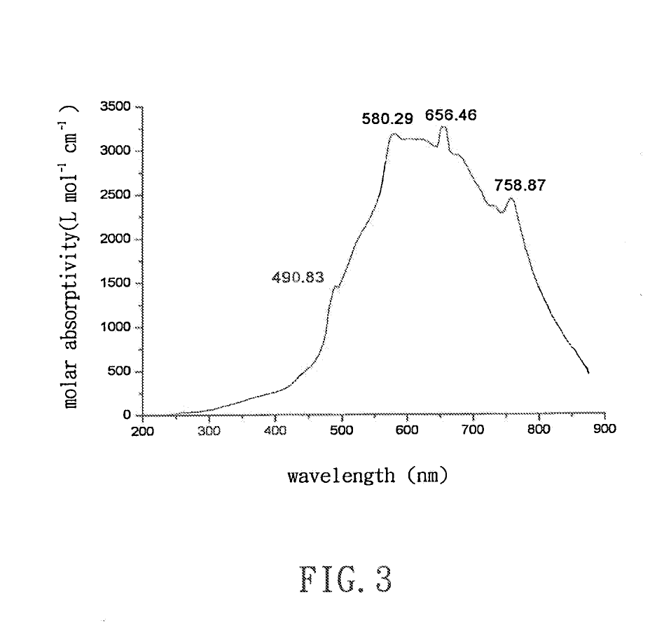

The absorption for the visible light-absorbing complex of Experiment 1 is shown in FIG. 3. The result indicates that the visible light-absorbing complex of Experiment 1 exhibits relatively broad visible absorption at 400 to 800 nm. The absorption peak for each of Experiments 2-1 to 2-9 was observed at about 516.95 nm. The absorption becomes higher with an increase in the concentration of the visible light-absorbing complex. The molar absorptivity at about 516.95 nm for each of Experiments 2-8, 2-3, and 2-9 was measured. The results are 11.86 L ol⁻¹cm⁻¹, 39.92 L mol⁻¹cm⁻¹, and 64.44 L mol⁻¹cm⁻¹, respectively. The results reveal that the greater the generation of the dendritic polymer, the greater will be the molar absorptivity. From the absorption results and the relationship between the molar absorptivity and the generation of the dendritic polymer, it is suggested that, in the dendritic polymer, the triazine group might be an electron-providing group, and the triazine group(s) interacts with the electron acceptor by virtue of π-π interaction, thereby resulting in charge transfer between the dendritic polymer and the electron acceptor.

In Experiments 3-1 to 3-9, the absorption peaks were observed at 487.05 nm, 667.99 nm, and 748.98 nm. The intensity of the absorbance becomes higher with an increase in the concentration of the visible light-absorbing complex. The molar absorptivity at about 487.05 nm, 667.99 nm, and 748.98 for each of Experiments 3-8, 3-1, and 3-9 was measured. The results are shown in Table 2.

TABLE 2

| | ε_{487.05} | ε_{667.99} | ε_{748.98} |
|---|---|---|---|
| Experiment | (L mol⁻¹cm⁻¹) | (L mol⁻¹cm⁻¹) | (L mol⁻¹cm⁻¹) |
| 3-8 | — | 3.94 | 20.64 |
| 3-1 | 61.99 | 26.20 | 29.43 |
| 3-9 | 33.81 | 47.71 | 31.63 |

—: not detected

In Experiments 4-1 to 4-11, when the concentration of the visible light-absorbing complex was less than 2.5×10⁻³ M (i.e., Experiments 4-4, 4-5, 4-6, 4-7, 4-10, and 4-11), two absorption peaks were observed at about 398.93 nm and 417.93 nm, and when the concentration of TCNE and the dendrimer were both increased to and greater than 2.5×10⁻³M, another new absorption peak at about 598.03 nm was observed. The intensity of the absorbance becomes higher with an increase in the concentration of the visible light-absorbing complex. The molar absorptivity at about 398.93 nm and 417.93 nm for each of Experiments 4-6, 4-10, and 4-11, and the molar absorptivity at about 598.03 nm for each of Experiments 4-3, 4-8, and 4-9 were measured. The results are shown in Table 3. It can be noted from Table 3 that, Experiment 4-9 containing G₃-N˜N-G₃ exhibits the greatest molar absorptivity at 598.03 nm. At 398.93 nm and 417.93 nm, Experiment 4-10 containing G₁-N˜N-G₁ exhibits the greatest molar absorptivity, and Experiment 4-6 containing G₂-N˜N-G₂ exhibits the weakest molar absorptivity. The factors affecting the intensity of the molar absorptivity are complicated and might include steric hindrance of the branch group and the number of the triaminotriazine moiety. That is, in Experiment 4-10, the greatest molar absorptivity might be attributed to the least steric hindrance from the terminal group, thereby resulting in strongest interaction between G₁-N˜N-G₁ and TCNE. In Experiment 4-11, the molar absorptivity greater than that in Experiment 4-6 might be attributed to the bigger number of the triaminotriazine moiety in G₃-N˜N-G₃ than that in G₂-N˜N-G₂.

TABLE 3

| | ε_{398.93} | ε_{417.93} | ε_{598.03} |
|---|---|---|---|
| Experiment | (L mol⁻¹cm⁻¹) | (L mol⁻¹cm⁻¹) | (L mol⁻¹cm⁻¹) |
| 4-8 | — | — | 27.60 |
| 4-3 | — | — | 27.60 |
| 4-9 | — | — | 461.31 |
| 4-10 | 6792.26 | 6790.32 | — |
| 4-6 | 3612.26 | 3590.00 | — |
| 4-11 | 5076.97 | 4945.16 | — |

—: not measured

In Experiment 5, the greatest absorption peak was observed at about 496.93 nm and the molar absorptivity (496.93) was 25.95 L mol⁻¹cm⁻¹. In Experiment 6, the absorption peaks were observed at about 391.03 nm, 408.98 nm, and 584.06 nm, and the molar absorptivity at 391.03 nm, 408.98 nm, and 584.06 nm were 280.00 Lmol⁻¹cm⁻¹, 281.94 Lmol⁻¹cm⁻¹, and 56.80 Lmol⁻¹cm⁻¹.

The aforesaid experimental results reveal that, although the triazine-based dendritic polymer has an absorption band at a wavelength less than 300 nm, after mixing with an electron acceptor, the absorption peaks of the visible light-absorbing complex shift to 400 to 800 nm. This might be attributed to the charge transfer between the triazine-based dendritic polymer and the electron acceptor. In addition, it should be noted that the range of the absorption wavelength of the visible light-absorbing complex could be controlled by virtue of mixing of the dendritic polymer of this invention with different types of the electron acceptor.

According to the present invention, the visible light-absorbing complex composed of the triazine-based dendritic polymer of formula (I) as an electron donor and an electron acceptor exhibits absorption at visible wavelength, and thus can be used in the organic photovoltaic device.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

1. A visible light-absorbing complex for an organic photovoltaic device comprising an electron acceptor and an electron donor, said electron donor having a triazine-based dendritic polymer formed of a core group (C) and branch groups emanating from said core group (C), each of said branch groups being composed of terminal groups (P) and a triazine-based moiety group, said triazine-based dendritic polymer being represented by the following formula (I): 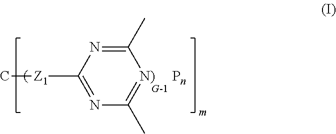
wherein G indicates the generation number of said triazine-based dendritic polymer and is an integer greater than 0, “G-1” indicating the layer number of said branch groups, n being the number of said terminal groups and representing 2^{(G-1)}, and m being the number of said branch groups emanating from said core group and ranging from 2 to 4,
wherein Z₁ of said triazine-based moiety group is a divalent group containing O or N, and an atom of Z₁ bonding to said triazine group of said triazine-based moiety group should be O or N; and
wherein, when G is 1, the core group should be a triazine-based core group having at least one triazine ring, and an atom of each of said terminal groups bonding to said triazine ring of said triazine-based core group should be O or N.

2. The visible light-absorbing complex of claim 1, wherein said core group (C) is a triazine-based core group.

3. The visible light-absorbing complex of claim 2, wherein, when m is 2, the triazine-based core group is 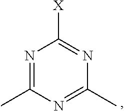
wherein X is halogen, a C₁˜C₂₀ alkyl group, a C₁˜C₂₀ aromatic group, OR₀, 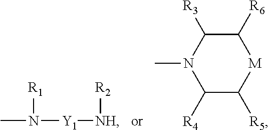
wherein R₀ is a C₁˜C₂₀ alkyl group or a C₁˜C₂₀ aromatic group, R₁ and R₂ are independently H or a C₁˜C₁₀ alkyl group, Y₁ is 1,4-cyclohexylene, 1,3-cyclohexylene, meta-phenylene, para-phenylene, or a C₁-C₁₀ alkylene group, M is NH, O, S, CH₂, N—R′, or CH—R″, R₃, R₄, R₅, and R₆ are independently H or a methyl group, in which R′ is a C₁˜C₂₀ alkyl group, a C₁˜C₂₀ aromatic group, 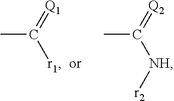
in which Q₁ and Q₂ are independently O or S, r₁ and r₂ are independently a C₁˜C₂₀ alkyl group or a C₁˜C₂₀ aromatic group, R″ is OH, Or₃, 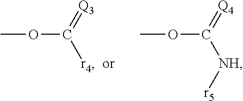
in which Q₃ and Q₄ are independently O or S, and r₃, r₄, and r₅ are independently a C₁˜C₂₀ alkyl group or a C₁˜C₂₀ aromatic group.

4. The visible light-absorbing complex of claim 2, wherein said triazine-based core group is 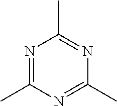
when m is 3.

5. The visible light-absorbing complex of claim 2, wherein said triazine-based core group 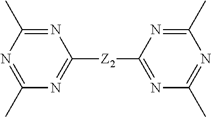
is when m is 4,
wherein Z₂ is a divalent group containing O or N, and each of the atoms of Z₂ bonding to the respective triazine group of said core group should be O or N.

6. The visible light-absorbing complex of claim 1, wherein, in the triazine-based moiety group, at least one of the atoms of Z₁ bonding to the respective one of said triazine groups, should be N.

7. The visible light-absorbing complex of claim 6, wherein, in each occurrence, Z₁ is 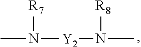
wherein, when R₇ and R₈ are independently H or a C₁˜C₁₀ alkyl group, Y₂ is a C₁-C₁₀ alkylene group, 1,4-cyclohexylene, 1,3-cyclohexylene, meta-phenylene, para-phenylene, or when R₇ and R₈ together form a C₂˜C₁₀ alkylene group, Y₂ is a C₁-C₁₀ alkylene group.

8. The visible light-absorbing complex of claim 7, wherein, in each occurrence, R₇ and R₈ are independently a C₁˜C₁₀ alkyl group.

9. The visible light-absorbing complex of claim 1, wherein, in each occurrence, said terminal group (P) is —NR₉R₁₀ or 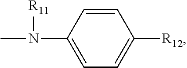
wherein R₉ and R₁₀ are independently H, a C₁˜C₁₀ alkyl group, -E₁-R₁₃, or -E₂-OR₁₄, and E₁ and E₂ are independently meta-phenylene or para-phenylene, R₁₃ and R₁₄ are independently H or a C₁˜C₂₀ alkyl group, R₁₁ is H or a C₁˜C₁₀ alkyl group, and R₁₂ is H, a C₁˜C₂₀ alkyl group, —OR₁₅, -E₃-R₁₆, or -E₄-OR₁₇, and E₃ and E₄ are meta-phenylene, and R₁₅, R₁₆, and R₁₇ are independently H or a C₁˜C₂₀ alkyl group.

10. The visible light-absorbing complex of claim 9, wherein, in each occurrence, said terminal group (P) is —NR₉R₁₀, and R₉ and R₁₀ are independently a C₄-C₈ alkyl group.

11. The visible light-absorbing complex of claim 5, wherein Z₂ has the same definition as Z₁ in claim 7.

12. The visible light-absorbing complex of claim 1, wherein said electron acceptor is selected from the group consisting of tetrafluoro-p-benzoquinone, 7,7,8,8-tetracyano-p-quinodimethane, tetracyanoethylene, and combinations thereof.

13-17. (canceled)

18. An organic photovoltaic device comprising the visible light-absorbing complex as claimed in claim 1.
